(19) United States
(12) Patent Application Publication
(10) Pub. No.: US 2025/0334996 A1
(43) Pub. Date: Oct. 30, 2025

(54) APPARATUSES AND METHODS FOR PHASE DETECTION

(71) Applicant: Micron Technology, Inc., Boise, ID (US)

(72) Inventor: Yasuo Satoh, Tsukuba (JP)

(73) Assignee: Micron Technology, Inc., Boise, ID (US)

(21) Appl. No.: 19/172,828

(22) Filed: Apr. 8, 2025

Related U.S. Application Data
(60) Provisional application No. 63/638,570, filed on Apr. 25, 2024.

(51) Int. Cl. G06F 1/08; G06F 1/12; H03K 19/20

(52) U.S. Cl. CPC G06F 1/08; G06F 1/12; H03K 19/20

(57) ABSTRACT

A phase detector circuit may receive a reference clock signal and a clock signal and detect a phase difference between the two clock signals and output a signal indicative of the phase difference. In some examples, the reference clock signal and the clock signal may be provided to multiple inputs of the phase detector circuit. In some examples, the phase detector circuit may include one or more NOR latches. In some examples, the phase detector circuit may include one or more NAND circuits.

### CROSS REFERENCE TO RELATED APPLICATION(S)

This application claims the benefit under 35 U.S.C. § 119 of the earlier filing date of U.S. Provisional Application Ser. No. 63/638,570 filed Apr. 25, 2024 the entire contents of which is hereby incorporated by reference in its entirety for any purpose.

### BACKGROUND

High data reliability, high speed memory access, lower power consumption and reduced chip size are features that are demanded from semiconductor memory. Typically, memories utilize a reference clock signal to control timing of operations. For example data may be transmitted or received based on a clock signal. The memory may receive an external clock signal and propagate the clock signal internally and/or generate additional internal clock signals based on the external clock signal. To ensure clock signals remain synchronized, memories may use various synchronization circuits such as delay lock loops, phase lock loops, and so on. The synchronization circuit may compare a clock signal to a reference clock signal. For example, the synchronization circuit may include a phase detector that detects a phase difference between the clock signal and the reference clock signal. Based on the comparison, the synchronization circuit may increase or decrease (e.g., add or remove) a delay to the clock signal to synchronize it with the reference clock signal.

However, as clock speeds increase, synchronization circuits may have difficulty correctly comparing clock signals and reference clock signals. Accordingly, synchronization circuits that can operate at higher frequencies may be desired.

### BRIEF DESCRIPTION OF THE DRAWINGS

FIG. 1 illustrates a schematic block diagram of a semiconductor device in accordance with an embodiment of the present disclosure.

FIG. 2 is a circuit diagram of an example of an existing phase detector circuit.

FIG. 3 is a timing diagram illustrating performance of the phase detector circuit shown in FIG. 2.

FIG. 4 is a circuit diagram of an example of a phase detector circuit according to embodiments of the present disclosure.

FIG. 5 is a block diagram of a portion of a synchronization circuit in accordance with embodiments of the present disclosure.

FIG. 6 is a timing diagram illustrating signals provided by the phase detector circuit shown in FIG. 2 and the phase detector circuit shown in FIG. 4.

### DETAILED DESCRIPTION

Certain details are set forth below to provide a sufficient understanding of embodiments of the disclosure. However, it will be clear to one having skill in the art that embodiments of the disclosure may be practiced without these particular details. Moreover, the particular embodiments of the present disclosure described herein are provided by way of example and should not be used to limit the scope of the disclosure to these particular embodiments.

This application describes examples of semiconductor devices including phase detector circuits. In some embodiments, the phase detector circuit may be included in a synchronization circuit, such as, or including, a delay locked loop DLL) circuit. The phase detector may allow the synchronization circuit to determine a phase difference between a clock signal and a reference clock signal and provide an appropriate delay to align (e.g., synchronize) the phases of the clock and reference clock signal.

A semiconductor device may receive an external clock signal. Internal clock signals may be generated by the semiconductor device based, at least in part, on the external clocks signal. The internal clock signals may be used to control timing of transmission of data or other operations of the semiconductor device. When the external clock signal is received at the semiconductor device, the clock phase of one or more internal clock signals based on the external clock signal may be delayed because of the inherent delay of the components of the semiconductor device. These delays may cause improper internal operation of the semiconductor device and/or may cause errors in communications with external devices (e.g., a memory controller).

To mitigate these delays, a clock path of the semiconductor device may include a synchronization circuit. The synchronization circuit may include one or more delay lines that allow the synchronization circuit to increase or decrease a delay of the internal clock signal to cause the internal clock signal to match the phase of the external clock signal. In some embodiments, the clock phase may be adjusted to match the phase of the external clock using DLL circuit, but other circuits may be used in other embodiments.

The phase detector circuit may detect a phase difference between the internal clock signal and the external clock signal (or other reference clock signal) and provide one or more signals indicating the detected phase difference (if any). Based on the signal provided by the phase detector circuit, the DLL circuit or other component of the synchronization circuit may adjust (e.g., increase or decrease) the delay applied to the internal clock signal to match the phase of the external clock signal (or other reference clock signal).

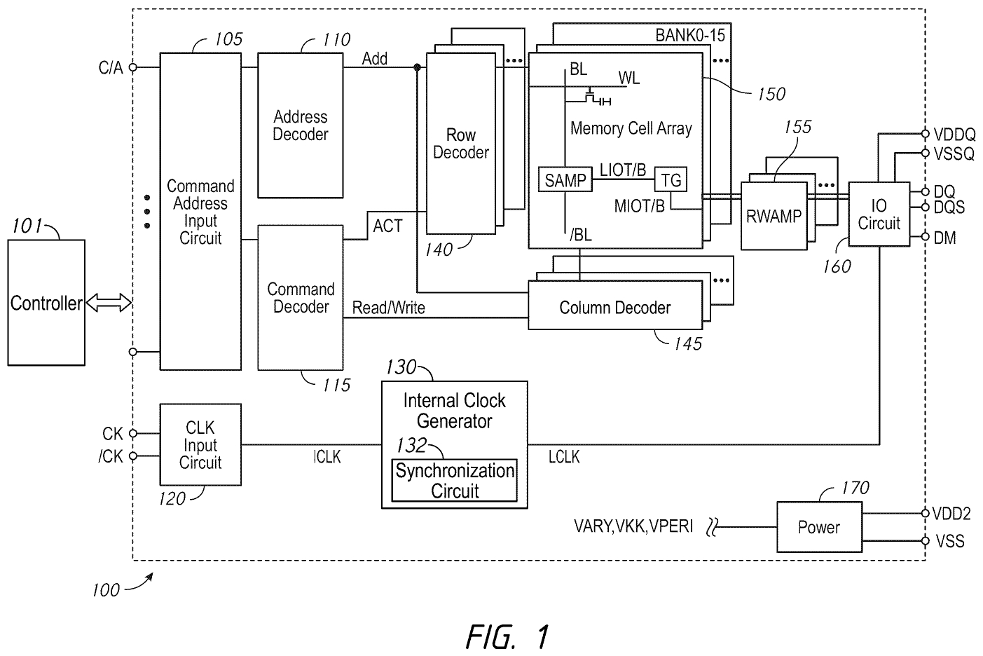

FIG. 1 illustrates a schematic block diagram of a semiconductor device in accordance with an embodiment of the present disclosure. The semiconductor device 100 includes a memory die. The memory die may include a command/address input circuit 105, an address decoder 110, a command decoder 115, a clock input circuit 120, internal clock generator 130, row decoder 140, column decoder 145, memory array 150, read/write amplifiers 155, I/O circuit 160, and power circuit 170.

In some embodiments, the semiconductor device 100 may include, without limitation, a dynamic random-access memory (DRAM) device, such as double data rate (DDR), low power DDR (LPDDR), or graphics DDR (GDDR), integrated into a single semiconductor chip, for example. The die may be mounted on an external substrate, for example, a memory module substrate, a mother board or the like.

The semiconductor device 100 may include a memory array 150. The memory array 150 includes a plurality of banks (BANK0-15), each bank including a plurality of word lines WL, a plurality of bit lines BL, and a plurality of memory cells MC arranged at intersections of the plurality of word lines WL and the plurality of bit lines BL. The selection of the word line WL is performed by a row decoder 140 and the selection of the bit line BL is performed by a column decoder 145. Sense amplifiers (SA) are located for their corresponding bit lines BL and connected to at least one respective local I/O line (LIOT/B), which is in turn coupled to a respective one of at least two main I/O line pairs (MIOT/B), via transfer gates (TG), which function as switches.

The semiconductor device 100 may employ a plurality of external terminals that include address and command terminals coupled to command/address bus (C/A), clock terminals CK and/CK, data terminals DQ, DQS, and DM, power supply terminals VDD2, VSS, VDDQ, and VSSQ. The external terminals may be used to communicate with an external device, such as controller 101. Controller 101 may be integrated with and/or in communication with a processor (not shown). In some embodiments, controller 101 may be included in a system on a chip (SoC).

The command/address terminals may be supplied with an address signal and a bank address signal from controller 101. The address signal and the bank address signal supplied to the address terminals are transferred, via the command/address input circuit 105, to an address decoder 110. The address decoder 110 receives the address signal and decodes the address signal to provide decoded address signal ADD. The ADD signal includes a decoded row address signal and a decoded column address signal. The decoded row address signal is provided to the row decoder 140, and a decoded column address signal is provided to the column decoder 145. The address decoder 110 also receives the bank address signal and supplies the bank address signal to the row decoder 140, the column decoder 145.

The command/address terminals may further be supplied with a command signal from the controller 101. The command signal may be provided, via the C/A bus, to the command decoder 115 via the command/address input circuit 105. The command decoder 115 decodes the command signal to generate various internal commands that include a row command signal ACT to select a word line and a column command signal Read/Write, such as a read command or a write command, to select a bit line, and a test mode signal.

Accordingly, when a read command is issued and a row address and a column address are timely supplied with the read command, read data is read from a memory cell in the memory array 150 designated by these row address and column address. The read data DQ is output to outside from the data terminals DQ (data), DQS (data strobe), and DM (data mask) via read/write amplifiers 155 and an input/output circuit 160. Similarly, when the write command is issued and a row address and a column address are timely supplied with this command, and then write data is supplied to the data terminals DQ, DQS, DM, the write data is received by data receivers in the input/output circuit 160, and supplied via the input/output circuit 160 and the read/write amplifiers 155 to the memory array 150 and written in the memory cell designated by the row address and the column address.

Turning to the explanation of the external terminals included in the semiconductor device 100, the clock terminals CK and/CK are supplied with an external clock signal and a complementary external clock signal, respectively. The external clock signals may be provided by the controller 101. The external clock signals may be supplied to a clock input circuit 120. The clock input circuit 120 may receive the external clock signals to generate an internal clock signal ICLK. The internal clock signal ICLK is supplied to an internal clock generator 130, which may generate one or more internal clock signals for use by various components of the semiconductor device 100. For example, as shown in FIG. 1, an internal clock signal LCLK is generated based on the received internal clock signal ICLK. The internal clock signal LCLK is supplied to the input/output circuit 160 and is used as a timing signal for determining an output timing of read data.

In some examples, the internal clock generator 130 may include a synchronization circuit 132. The synchronization circuit 132 may include a delay line that includes one or more adjustable delays (not shown) that can be used to increase or decrease a delay applied to a clock signal provided to the delay line. The delays may be adjusted to synchronize (e.g., align) the phases of two or more clock signals. For example, the delay line may add or remove delays applied to the LCLK signal to align the phase of the LCLK signal with the ICLK signal.

The synchronization circuit 132 may further include a phase detector circuit (not shown in FIG. 1). The phase detector may receive the ICLK signal as a reference signal and the generated LCLK signal may be fed back to the phase detector (e.g., from the delay line). The phase detector detects a phase difference between LCLK and ICLK and provides a signal based on the comparison. The signal provided by the phase detector may be used by the synchronization circuit 132 to adjust the one or more adjustable delays to increase or decrease the delay applied to LCLK. Of course, if the phase detector determines the phase difference is ‘0’ (e.g., no phase difference), then the synchronization circuit 132 may not adjust the adjustable delays. In some embodiments, the phase detector and/or adjustable delays may be included in a DLL circuit included in the synchronization circuit 132.

While this disclosure provides examples of operation of the synchronization circuit 132 and phase detector using internal clock signal ICLK and internal clock signal LCLK, the principles of operation are not so limited. The internal clock generator 130 is not limited to generating the LCLK signal, and additional and/or different internal clock signals may be generated by internal clock generator 130, which may be provided to other and/or additional components of the semiconductor device 100. Other signals besides ICLK may be used as a reference signal in other examples. Further, the semiconductor device 100 may include more than one synchronization circuit 132, nor is the synchronization circuit 132 limited to the internal clock generator 130. For example, the clock input circuit 120 may include one or more synchronization circuits 132.

The power supply terminals are supplied with power supply potentials VDD2 and VSS. These power supply potentials VDD2 and VSS are supplied to an internal voltage generator circuit 170. The internal voltage generator circuit 170 generates various internal potentials VARY, VKK, VPERI, and the like based on the power supply potentials VDD2 and VSS. The internal potential VARY is mainly used in the sense amplifiers included in the memory array 150, the internal potential VKK is mainly used in the row decoder 140, and the internal potential VPERI is used in many other circuit blocks.

The power supply terminals are also supplied with power supply potentials VDDQ and VSSQ. These power supply potentials VDDQ and VSSQ are supplied to the input/output circuit 160. The power supply potentials VDDQ and VSSQ are typically the same potentials as the power supply potentials VDD2 and VSS, respectively. However, the dedicated power supply potentials VDDQ and VSSQ are used for the input/output circuit 160 so that power supply noise generated by the input/output circuit 160 does not propagate to the other circuit blocks.

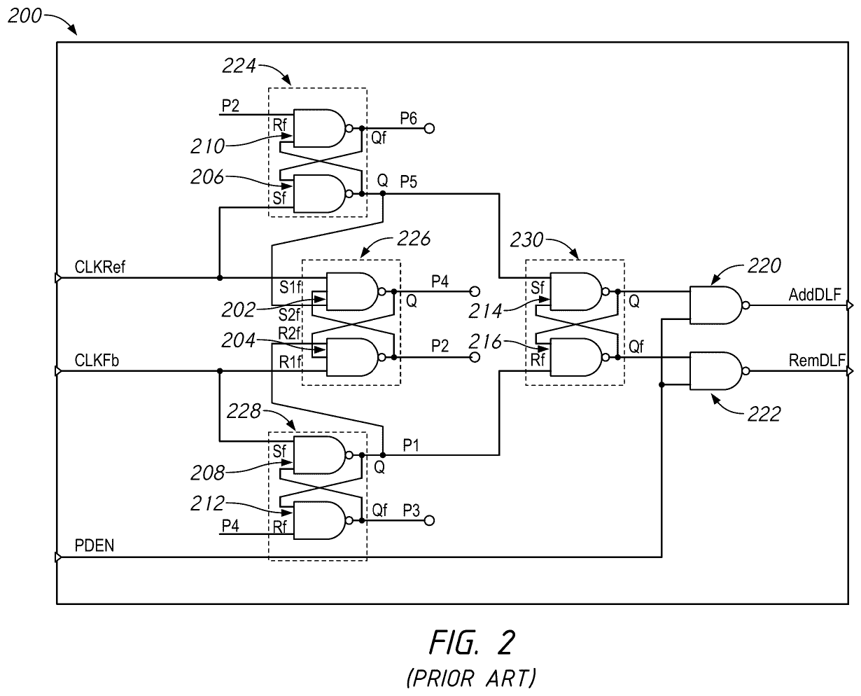

FIG. 2 is a circuit diagram of an example of an existing phase detector circuit. The phase detector (PD) circuit 200 is an arbiter-style PD circuit and may be included in or associated with a synchronization circuit, such as one included in a clock generator. The PD circuit 200 receives a reference clock signal CLKRef and a feedback clock signal CLKFb. The feedback clock signal may be an internal clock signal generated by a clock generator fed back to the phase detector 200 (e.g., from a delay line or other circuit).

The PD circuit 200 includes several NAND logic circuits 202-222. NAND 202 may receive CLKRef, the output P5 of NAND 206, and the output of NAND 204 as inputs and provide an output P4. NAND 204 may receive CLKFb, the output P1 of NAND 208 as inputs and provide output P2.

CLKRef may also be provided as an input to NAND 206. NAND 206 may further receive the output P6 of NAND 210 and provide the output P5 to NAND 202 and NAND 214. NAND 210 may receive the output P5 from NAND 206 and output P2 from NAND 204 as inputs and provide output P6.

CLKFb may also be provided as an input to NAND 208. NAND 208 may further receive the output P3 of NAND 213 and provide the output P1 to NAND 204 and NAND 216. NAND 212 may receive the output P1 from NAND 208 and output P4 from NAND 202 as inputs and provide output P3.

NAND 214 may receive the output P5 from NAND 206 and the output of NAND 216 as inputs. The output of NAND 214 may be provided to NAND 216 and NAND 220. NAND 216 may receive output P1 from NAND 208 and the output of NAND 214 as inputs. The output of NAND 216 may be provided to NAND 222.

Both NAND 220 and 222 may receive a phase detector enable signal PDEN. PDEN may be logic high when PD circuit 200 is enabled and logic low when PD circuit 200 is disabled. However, PDEN may be provided from a fixed voltage which maintains a high logic state. When PDEN is logic high, NAND 220 provides an add delay signal AddDLF, and NAND 222 provides a remove delay signal RemDLF. The AddDLF and RemDLF signals may be used by one or more components of a synchronization circuit to add or remove delays applied to CLKFb to align the phase of CLKRef and CLKFb. AddDLF and RemDLF may be active low signals.

As is apparent to those skilled in the art, PD circuit 200 can be considered to be made of four latches: S-R latches 224, 226, 228, and 230. These latches have hold, set, reset, and invalid states based on the inputs. The latches may be unstable when put in an invalid state, typically when both inputs to the latch are logic low, and the outputs of the latch may be unpredictable during and/or after the invalid state (e.g., until the latch has stabilized in a set, reset, or hold state).

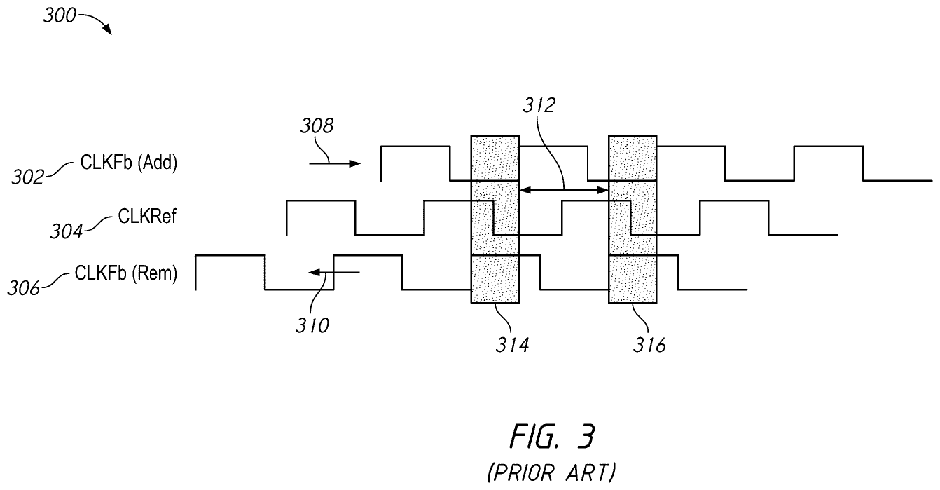

FIG. 3 is a timing diagram illustrating performance of the phase detector circuit shown in FIG. 2. The top line 302 illustrates a feedback clock signal CLKFb where additional delay is required to align the phase of CLKFb with a reference clock signal CLKRef as indicated by arrow 308. The middle line 304 illustrates the reference clock signal CLKRef. The bottom line 306 illustrates a feedback clock signal CLKFb where delay is required to be reduced (removed) to align the phase of the CLKFb with the reference clock signal as indicated by arrow 310.

Due to various issues, such as speed of transistors, time for latches to stabilize from unstable states, propagation delays, and/or other factors, the PD circuit 200 has offsets for fall-to-rise phase differences (180 degree phase difference). That is, phase differences detected by the phase detector may not be accurate. In particular the PD circuit 200 has a relatively large offset between a fall in the CLKRef signal and the rise of CLKFb signal. These offsets (sometimes referred to as offset errors) may create “dead zones” 314 and 316 where the output of the PD circuit 200 is unreliable. The dead zones 314, 316 reduce the operating range, indicated by arrow 312, of the PD circuit 200.

The operating range of the PD circuit 200 may be further reduced as clock speeds increase. Accordingly, a phase detector circuit that may provide reduced offsets, particularly for fall (Ref)-to-rise (Fb) behaviors is disclosed.

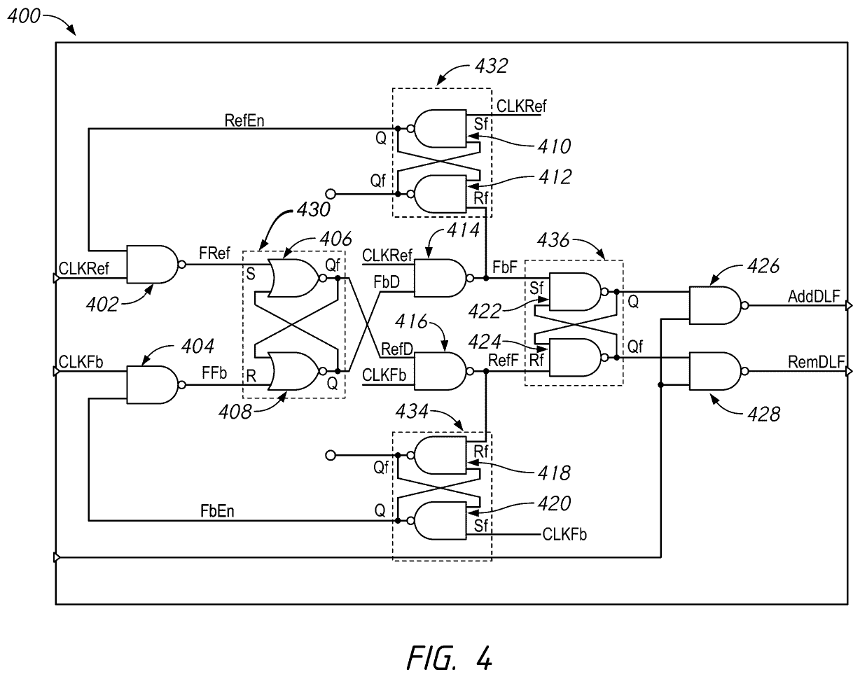

FIG. 4 is a circuit diagram of an example of a phase detector circuit according to embodiments of the present disclosure. The phase detector (PD) circuit 400 is an arbiter-style PD circuit and may be included in or associated with a synchronization circuit, such as synchronization circuit 132. The PD circuit 400 receives a reference clock signal CLKRef and a feedback clock signal CLKFb. The reference clock signal may be an internal clock signal (e.g., ICLK) or an external clock signal (e.g., CK,/CK) in some embodiments. The feedback clock signal may be an internal clock signal (e.g., LCLK) generated by a clock generator fed back to the PD circuit 400 (e.g., from a delay line or other circuit).

While PD circuit 400 also has four S-R latches (latches 430, 432, 434, and 436), in contrast to PD circuit 200, all of the logic gates have two inputs, not three inputs. Additionally, one of the latches, latch 430 is a NOR logic circuit latch rather than a NAND logic circuit latch. Further, in contrast to PD circuit 200, as will be described in more detail below, in PD circuit 400 the clock signals are each provided directly to three logic circuits rather than only two logic circuits.

The PD circuit 400 includes a NAND 402 that receives CLKRef and RefEn as inputs. RefEn is provided by NAND 410 (which also receives CLKRef as an input). NAND 402 provides signal FRef as an output to NOR 406. The PD circuit 400 further includes a NAND 404 that receives CLKFb and FbEn as inputs. FbEn is provided by NAND 420 (which also receives CLKFb as an input). NAND 404 provides signal FFb to NOR 408. NOR 406 and NOR 408 are cross-coupled such that each receives an output of the other as an input. The output RefD is provided from NOR 406 to NAND 416 and the output FbD is provided from NOR 408 to NAND 414. Similar to NAND 410 and 420, NAND 414 and 416 also receive the clock signals. In particular, NAND 414 receives CLKRef, and NAND 416 receives CLKFb.

The output FbF of NAND 414 is provided to NAND 412. NAND 410 and 412 are cross-coupled such that each receives the output of the other as an input. As noted previously, NAND 410 receives CLKRef and outputs RefEn. The output RefF of NAND 416 is provided to NAND 418. NAND 418 and 420 are cross-coupled such that each receives the output of the other as an input. As noted previously, NAND 420 receives CLKFb and outputs FbEn.

The output FbF of NAND 414 is further provided to NAND 422, and the output RefF of NAND 416 is further provided to NAND 424. NAND 422 and 424 are cross-coupled such that each receives the output of the other as an input. The output of NAND 422 is provided to NAND 426 and the output of NAND 424 is provided to NAND 428.

Both NAND 426 and 428 may receive a phase detector enable signal PDEN. IN some embodiments, PDEN may be logic high when PD circuit 400 is enabled and logic low when PD circuit 400 is disabled. In other embodiments, PDEN may be provided from a fixed voltage which maintains a high logic state. When PDEN is logic high, NAND 426 provides an add delay signal AddDLF, and NAND 428 provides a remove delay signal RemDLF. The AddDLF and RemDLF signals may be used by one or more components of a synchronization circuit (e.g., synchronization circuit 132) to add or remove delays applied to CLKFb to align the phase of CLKRef and CLKFb. AddDLF and RemDLF may be active low signals in some embodiments.

By providing the clock signals CLKRef and CLKFb at different locations throughout the PD circuit 400, the propagation delays of CLKRef and CLKFb through the PD circuit 400 may be different than the propagation delays through the PD circuit 200 in some embodiments. Without being limited to a particular theory of operation, altering the propagation delays of the clock signals may allow for PD circuit 400 to have smaller offsets compared to PD circuit 200, particularly for fall (Ref)-to-rise (Fb). However, other and/or additional features of PD circuit 400 may contribute to the reduction of offsets compared to PD circuit 200.

In some embodiments, PD circuit 400 may provide one or more additional advantages over PD circuit 200. While PD circuit 400 has more logic gates than PD circuit 200, in some embodiments, PD circuit 400 has a smaller layout than PD circuit 200. For example, PD circuit 200 is approximately 7 microns long whereas PD circuit 400 is approximately 4.5 microns long in some embodiments. This is because the components of PD circuit 400 may use smaller transistors than PD circuit 200. Further, nearly all of the components in PD circuit 200 operate at a higher voltage level. In contrast, in some embodiments, most of the components in PD circuit 400 may operate at a lower voltage.

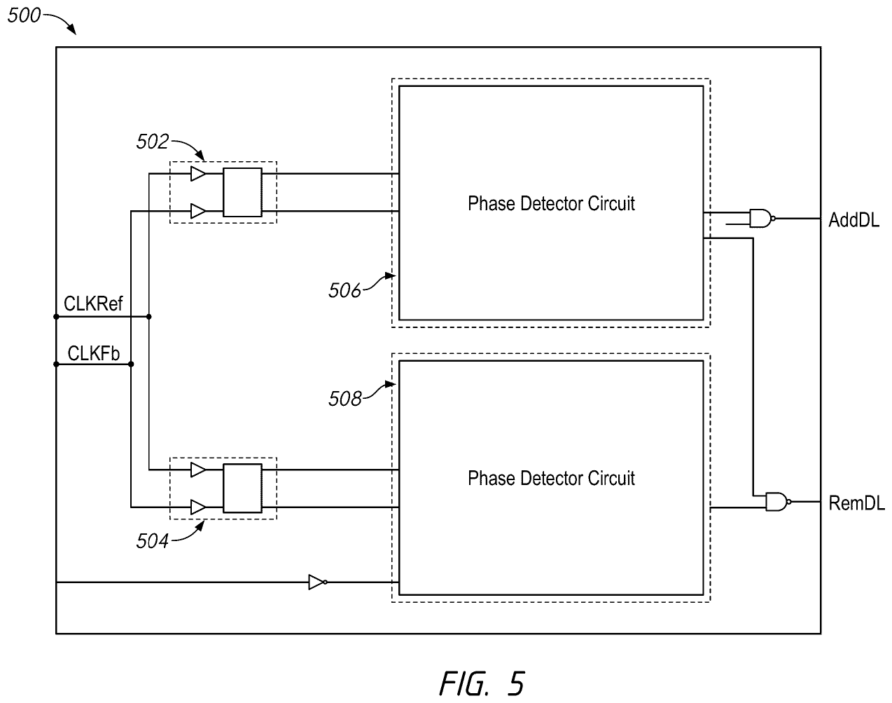

FIG. 5 is a block diagram of a portion of a synchronization circuit in accordance with embodiments of the present disclosure. Synchronization circuit 500 may be included in synchronization circuit 132 in some embodiments. Synchronization circuit 500 may allow for programmable hysteresis for synchronizing phases of clock signals. In some applications, it may be desirable to allow for some degree of misalignment of the phases of clock signals that the synchronization circuit is synchronizing. This may reduce time delays and/or power consumption related to adjusting adjustable delays in the synchronization circuit 500. The PD circuit 400 may be compatible with hysteresis circuits of the synchronization circuit 500.

Synchronization circuit 500 may include two programmable delay circuits 502 and 504. Each delay circuit 502, 504 may receive a reference clock signal CLKRef and a feedback clock signal CLKFb. The reference clock signal may be an internal clock signal (e.g., ICLK) or an external clock signal (e.g., CK,/CK) in some embodiments. The feedback clock signal may be an internal clock signal (e.g., LCLK) generated by a clock generator fed back to the programmable delay circuits 502, 504 (e.g., from a delay line or other circuit).

The delay programmed into each programmable delay circuit 502, 504 may set the desired hysteresis range of the synchronization circuit 500. For example, the delay programmed into programmable delay circuit 502 may provide an amount CLKFb is permitted to be “ahead of” CLKRef and the delay programmed into programmable delay circuit 504 may provide an amount CLKFb is permitted to be “behind” CLKRef.

The outputs of programmable delay circuit 502 are provided to a phase detector (PD) circuit 506 and the outputs of programmable delay circuit 504 are provided to PD circuit 508. PD circuit 506 and/or PD circuit 508 may include PD circuit 400 in some embodiments. The AddDL output of PD circuit 506 may be used as the hysteresis AddDL output and the RemDL output of PD circuit 508 may be used as the hysteresis RemDL output. The hysteresis AddDL and RemDL signals may indicate a change in the delay of CLKFb is necessary when the phase difference between CLKRef and CLKFb falls outside the range determined by programmable delay circuits 502, 504. Thus, by using two PD circuits with different delayed inputs, the synchronization circuit 500 can have hysteresis that permits acceptable phase differences between CLKRef and CLKFb.

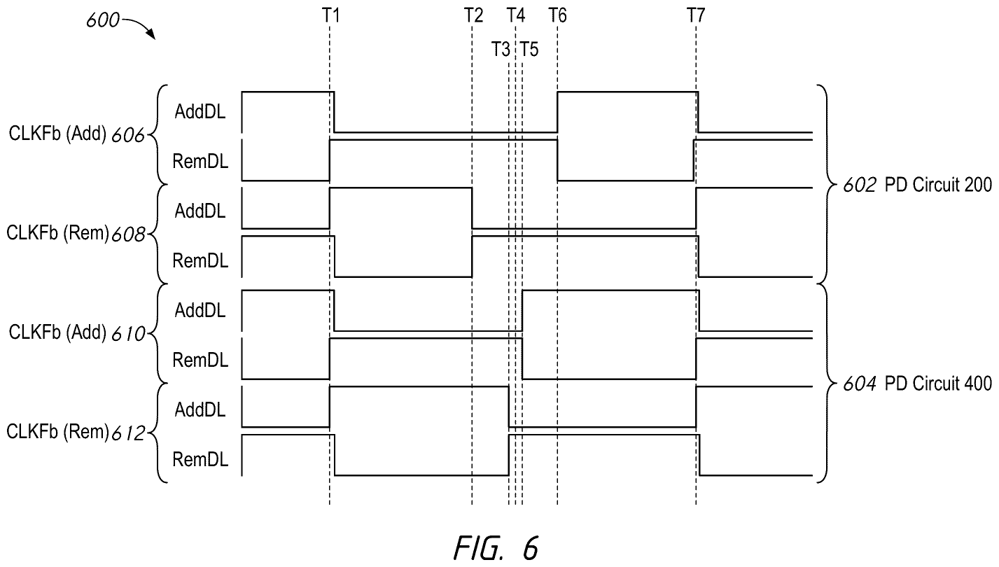

FIG. 6 is a timing diagram illustrating signals provided by the phase detector circuit shown in FIG. 2 and the phase detector circuit shown in FIG. 4. The top half 602 of timing diagram 600 illustrates signals provided by PD circuit 200, and the bottom half 604 of timing diagram 600 illustrates signals provided by PD circuit 400. Signals AddDL and RemDL shown in sections 606 and 610 are signals generated by the phase detector circuits responsive to a feedback clock CLKFb signal (not shown) that is “ahead” of a reference clock signal CLKRef (not shown) that requires a delay to be increased (e.g., added) to synchronize phases with CLKRef, indicated by CLKFb (Add). Signals AddDL and RemDL shown in sections 608 and 612 are signals generated by the phase detector circuits responsive to a CLKFb signal that is “behind” a CLKRef signal that requires a delay to be reduced (e.g., removed) to synchronize phases with CLKRef, indicated by CLKFb (Rem).

Times T1 and T7 indicate times when CLKRef and CLKFb have a zero degree phase difference (e.g., in-phase, synchronized). As shown in timing diagram 600, for both CLKFb (Add) and CLKFb (Rem), the AddDL and RemDL signals for both PD circuit 200 and PD circuit 400 adjust appropriately when, or close to when, CLKFb and CLKRef are in phase.

Time T4 indicates a time when CLKRef and CLKFb are 180 degrees out of phase where CLKRef is falling and CLKFb is rising. For PD circuit 200, when CLKFb is ahead, AddDL does not go high and RemDL does not go low until time T6. When CLKFb is behind, AddDL goes low and RemDL goes high at time T2. Thus, the phase differences indicated by AddDL and RemDL for PD 200 have an offset error, indicating an incorrect phase relationship between CLKFb and CLKRef.

Turning to PD circuit 400, for CLKFb (Add), AddDL goes high and RemDL goes low at time T5, which is closer to time T4 than time T6. Similarly, for CLKFb (rem), AddDL goes low and RemDL goes high at time T3, which is closer to time T4 than time T2. Thus the offset of PD circuit 400 is less than the offset for PD circuit 200. The reduced offset of PD circuit 400 may reduce the dead zones and increase the operating range of PD circuit 400. In some embodiments, this may allow PD circuit 400 to be used at faster clock speeds than PD circuit 200.

The synchronization circuits disclosed herein may provide phase detectors with reduced offsets compared to existing phase detectors. This may improve operating ranges and increase clock speeds at which the synchronization circuit can operate at. In some embodiments, providing the clock signals to be synchronized to additional points in the phase detector (e.g., each clock signal provided to three logic circuits) compared to existing phase detectors as disclosed herein may alter the propagation delays of the clock signals through the phase detector. The different propagation delays and/or other factors may improve performance of the phase detector. However, performance of the phase detectors disclosed herein may be based on additional and/or other factors in some embodiments.

From the foregoing it will be appreciated that, although specific embodiments of the disclosure have been described herein for purposes of illustration, various modifications may be made without deviating from the spirit and scope of the disclosure. Accordingly, the disclosure is not limited except as by the appended claims.

What is claimed is:

1. An apparatus comprising:
a first logic circuit configured to receive a first clock signal;
a second logic circuit configured to receive a second clock signal;
a first latch circuit configured to receive the first clock signal and provide a first output to the first logic circuit;
a second latch circuit configured to receive the second clock signal and provide a second output to the second logic circuit;
a third latch circuit coupled to the first and second logic circuits;
a third logic circuit configured to receive the first clock signal;
a fourth logic circuit configured to receive the second clock signal, wherein the third and fourth logic circuits are configured to receive outputs from the third latch; and
a fourth latch circuit configured to receive outputs from the third and fourth output circuits.

2. The apparatus of claim 1, further comprising:
a fifth logic circuit configured to receive a third output from the fourth latch circuit; and
a sixth logic circuit configured to receive a fourth output from the fourth latch circuit.

3. The apparatus of claim 2, wherein the fifth logic circuit is configured to provide a fifth output indicative of a delay to be added to the second clock signal and the sixth logic circuit is configured to provide a sixth output indicative of a delay to be removed from the second clock signal.

4. The apparatus of claim 2, wherein the fifth logic circuit and the second logic circuit are configured to receive an enable signal as a further input.

5. The apparatus of claim 2, wherein the fifth and sixth logic circuits comprise NAND logic circuits.

6. The apparatus of claim 1, wherein the first, second, third, and fourth latch circuits comprise S-R latches.

7. The apparatus of claim 6, wherein the first, second, and fourth latch circuits comprise NAND S-R latches.

8. The apparatus of claim 6, wherein the third latch circuit comprises a NOR S-R latch.

9. The apparatus of claim 1, wherein an output of the third logic circuit is further provided to the first latch circuit and an output of the fourth logic circuit is further provided to the second latch circuit.

10. The apparatus of claim 1, wherein the first, second, third, and fourth logic circuits comprise NAND logic circuits.

11. A synchronization circuit configured to synchronize a first clock signal and a second clock signal, the synchronization circuit comprising:
a first programmable delay circuit configured to receive the first and second clock signals and provide the first and second clock signals with a first delay;
a second programmable delay circuit configured to receive the first and second clock signals and provide the first and second clock signals with a second delay;
a first phase detector configured to receive the first and second clock signals with the first delay; and
a second phase detector configured to receive the first and second clock signals with the second delay,
wherein the first phase detector and the second phase detector each comprise:
at least two logic gates configured to receive the first clock signal;
at least two logic gates configured to receive the second clock signal;
at least one latch circuit configured to receive the first clock signal; and
at least one latch circuit configured to receive the second clock signal.

12. The synchronization circuit of claim 11, wherein the first delay determines an amount the second clock signal can be ahead of the first clock signal before the synchronization circuit increases a delay of the second clock signal, and wherein the second delay determines an amount the second clock signal can be behind the first clock signal before the synchronization circuit decreases the delay of the second clock signal.

13. The synchronization circuit of claim 11, wherein the first phase detector and the second phase detector are each configured to provide a first signal indicating an amount of delay to add to the second clock signal and a second signal indicating an amount of delay to remove from the second clock signal.

14. The synchronization circuit of claim 13, wherein the synchronization circuit is configured to use the first signal from the first phase detector to add the delay to the second clock signal and use the second signal from the second phase detector to remove the delay from the second clock signal.

15. The synchronization circuit of claim 11, wherein the at least one latch circuit configured to receive the first clock signal and the at least one latch circuit configured to receive the second clock signal each comprise a NAND S-R latch circuit.

16. The synchronization circuit of claim 11, wherein the first phase detector circuit and the second phase detector each further comprise a NOR S-R latch circuit configured to receive a first output from at least one of the at least two logic gates configured to receive the first clock signal and a second output from at least one of the at least two logic gates configured to receive the second clock signal.

17. A phase detector circuit comprising:
a first latch circuit configured to receive a reference clock signal;
a second latch circuit configured to receive a feedback clock signal;
a first logic circuit configured to receive the reference clock signal and provide a first output to the first latch circuit;
a second logic circuit configured to receive the feedback clock signal and provide a second output to the second latch;
a third logic circuit configured to receive the reference clock signal and a third output from the first latch circuit; and
a fourth logic circuit configured to receive the feedback clock signal and a fourth output from the second latch circuit.

18. The phase detector circuit of claim 17, further comprising a third latch circuit configured to receive a fifth output from the third logic circuit and a sixth output from the fourth logic circuit.

19. The phase detector circuit of claim 18, wherein the first logic circuit is configured to receive a seventh output from the third latch circuit and an eighth output from the third latch circuit.

20. The phase detector circuit of claim 17, further comprising a fourth latch circuit configured to receive the first output and the second output.
